(19) United States
(12) Patent Application Publication
(10) Pub. No.: US 2026/0190902 A1
(43) Pub. Date: Jul. 2, 2026

(54) SUBSTRATE TREATMENT APPARATUS AND SUBSTRATE TREATMENT METHOD

(71) Applicant: SEMES CO., LTD., Cheonan-si (KR)

(72) Inventors: Chang Suk OH, Cheonan-si (KR); Eun Woo PARK, Suwon-si (KR); Ki Sang EUM, Cheonan-si (KR)

(21) Appl. No.: 19/370,893

(22) Filed: Oct. 28, 2025

(30) Foreign Application Priority Data
Dec. 31, 2024 (KR) 10-2024-0202269

(51) Int. Cl. H01L 21/67; H01L 21/02; H01L 21/687

(52) U.S. Cl. CPC H10P 72/0414; H10P 70/52; H10P 72/7606; H10P 72/7618

(57) ABSTRACT

A substrate treatment apparatus includes a treatment container having a treatment space for a substrate, a support portion provided in the treatment space, and configured to support the substrate, and a rotary nozzle unit provided in the treatment space, the rotary nozzle unit configured to spray a treatment liquid onto a central region of a lower surface of the substrate by rotating about a rotational shaft within a first angular range, and to spray the treatment liquid onto an edge region of the lower surface of the substrate by rotating about the rotational shaft within a second angular range.

### CROSS-REFERENCE TO RELATED APPLICATION(S)

This application claims benefit of priority to Korean Patent Application No. 10-2024-0202269 filed on Dec. 31, 2024 in the Korean Intellectual Property Office, the disclosure of which is incorporated herein by reference in its entirety.

### TECHNICAL FIELD

The present disclosure relates to a substrate treatment apparatus and a substrate treatment method for cleaning a lower surface of a substrate.

In general, a manufacturing process of a semiconductor substrate a may be subdivided into a thin film process of depositing a thin film on a glass substrate, a photolithography process for forming the thin film into a desired pattern, and an etching process for etching the thin film according to the pattern. The semiconductor substrate may be manufactured by repeatedly performing such processes. In addition, before or after such processes are performed, a cleaning process for removing particles remaining on the substrate may be performed.

In general, the cleaning process may be performed by supplying a cleaning liquid to both surfaces of the substrate. For example, an upper surface of the substrate may be cleaned by a cleaning liquid supplied by an upper fluid supply portion provided above a support member supporting the substrate, and a lower surface of the substrate may be cleaned by a cleaning liquid supplied by a lower fluid supply portion provided between the support member and the substrate.

In this case, since a fluid supply portion for supplying a treatment liquid may have a fixed position, such that the number of nozzles may be increased in order to cover an area of the substrate, which may cause an increase in exhaust volume.

### SUMMARY

An aspect of the present disclosure is to provide a substrate treatment apparatus in which a position of a nozzle unit is movable, such that both a central region and an edge region of a substrate may be cleaned with a minimum number of nozzles, and a substrate treatment method using the same.

Another aspect of the present disclosure is to provide a substrate treatment apparatus capable of minimizing scattering of a treatment liquid without contaminating a spin chuck when a nozzle unit moves, and a substrate treatment method using the same.

The aspects of the present disclosure are not limited thereto, and it may be understood by those skilled in the art that other technical issues not mentioned herein may be derived from the configurations described in the following specification and drawings.

According to an aspect of the present disclosure, there is provided a substrate treatment apparatus including a treatment container having a processing space, a support portion provided in the processing space, the support portion configured to support the substrate, and a rotary nozzle unit provided in the processing space, the rotary nozzle unit configured to spray a treatment liquid onto a central region of a lower surface of the substrate by rotating about a rotational shaft within a first angular range, and to spray the treatment liquid onto an edge region of the lower surface of the substrate by rotating about the rotational shaft within a second angular range.

According to another aspect of the present disclosure, there is provided a substrate treatment method including carrying a substrate into a processing space of a treatment container, spraying a treatment liquid onto a central region of a lower surface of the substrate by rotating a rotary nozzle unit about a rotational shaft within a first angular range, and spraying, by the rotary nozzle unit, the treatment liquid onto an edge region of the lower surface of the substrate by rotating the rotary nozzle unit about the rotational shaft within a second angular range.

According to another aspect of the present disclosure, there is provided a substrate treatment apparatus including a treatment container having a processing space, a support portion provided in the processing space, and configured to support the substrate, and a rotary nozzle unit provided in the processing space, and configured to spray a treatment liquid onto a central region of a lower surface of the substrate by rotating about a rotational shaft within a first angular range, and to spray the treatment liquid onto an edge region of the lower surface of the substrate by rotating about the rotational shaft within a second angular range. The rotary nozzle unit may include a housing formed in a cup shape, and having an arcuate curved surface, an internal space and an upper opening, a nozzle portion provided in the internal space of the housing, and configured to spray a treatment liquid toward the lower surface of the substrate, an intake portion provided in the internal space of the housing, and configured to intake the sprayed treatment liquid, a gas injection portion provided along one surface of an inner wall of the housing having the arcuate curved shape, and configured to inject gas, a cover member protruding outwardly in a direction opposing one surface on which the gas injection portion is disposed, and a drive unit configured to rotate the rotary nozzle unit about the rotational shaft and to move the rotary nozzle unit in a vertical direction.

According to example embodiments of the present disclosure, a substrate treatment apparatus in which a position of a nozzle unit is movable, such that both a central region and an edge region of a substrate is cleaned with a minimum number of nozzles, and a substrate treatment method using the same may be provided.

According to example embodiments of the present disclosure, a substrate treatment apparatus capable of minimizing scattering of a treatment liquid without contaminating a spin chuck when a nozzle unit moves, and a substrate treatment method using the same may be provided.

The effects of the present disclosure are not limited to the above-described effects, and it may be understood by those skilled in the art that other effects not mentioned may be derived from the configurations described in the following specification and drawings.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a top view of a substrate treatment apparatus according to an example embodiment of the present disclosure;

FIG. 2 is a view of the substrate treatment apparatus of FIG. 1 taken along line A-A;

FIG. 3 is a view of the substrate treatment apparatus of FIG. 1 taken along line B-B;

FIG. 4 is a perspective view of a substrate treatment apparatus according to an example embodiment of the present disclosure;

FIG. 5 is a perspective view of a rotary nozzle unit according to an example embodiment of the present disclosure;

FIG. 6 is a cross-sectional view of a rotary nozzle unit according to an example embodiment of the present disclosure;

FIGS. 7 to 10 illustrate an example embodiment in which a rotary nozzle unit rotates about a rotational shaft at a predetermined angle; and

FIG. 11 is a flowchart of a substrate treatment method according to an example embodiment of the present disclosure.

### DETAILED DESCRIPTION

Hereinafter, preferred example embodiments will be described in detail, such that the disclosure could be easily carried out. In describing example embodiments of the present disclosure, when it is determined that a detailed description of a known technology related to the present disclosure may unnecessarily obscure the gist of the present disclosure, a detailed description thereof will be omitted. In addition, the same reference numerals are used throughout the drawings with respect to components having similar functions and actions. In addition, in the present specification, terms such as “upper,” “upper portion,” “upper surface,” “lower,” “lower portion,” “lower surface,” and “side surface” are based on the drawings, may vary depending on a direction in which an element or component is actually arranged.

In addition, it will be understood that “comprises,” “comprising,” “includes,” and “including” specify the presence of stated features, integers, operations, operations, elements, components or a combination thereof, but do not preclude the presence or addition of one or more other features, integers, operations, operations, elements, components, and/or groups thereof.

The present disclosure may be implemented in various forms, and is not limited to the example embodiments described herein.

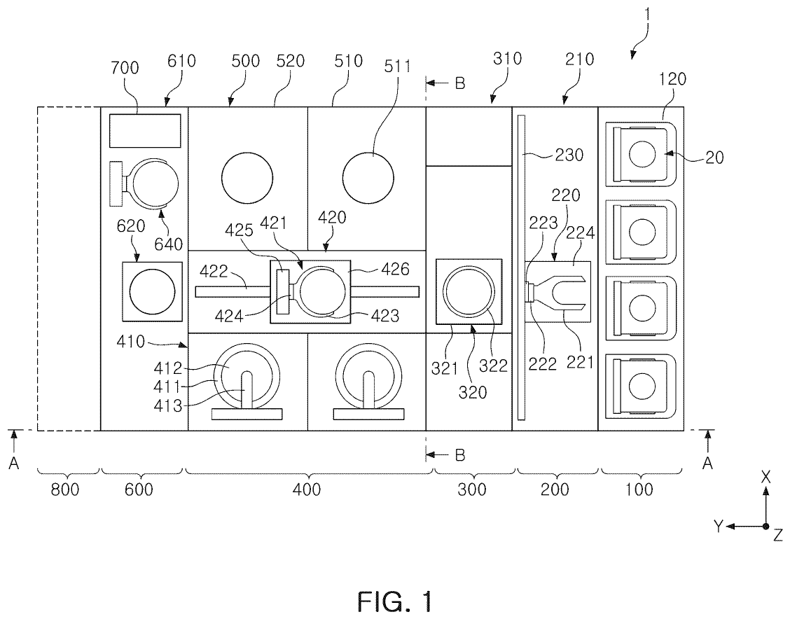

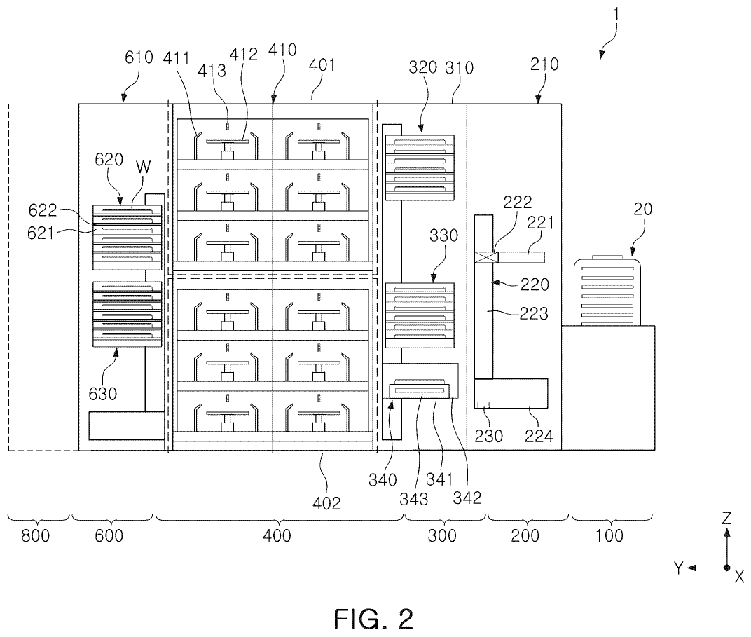

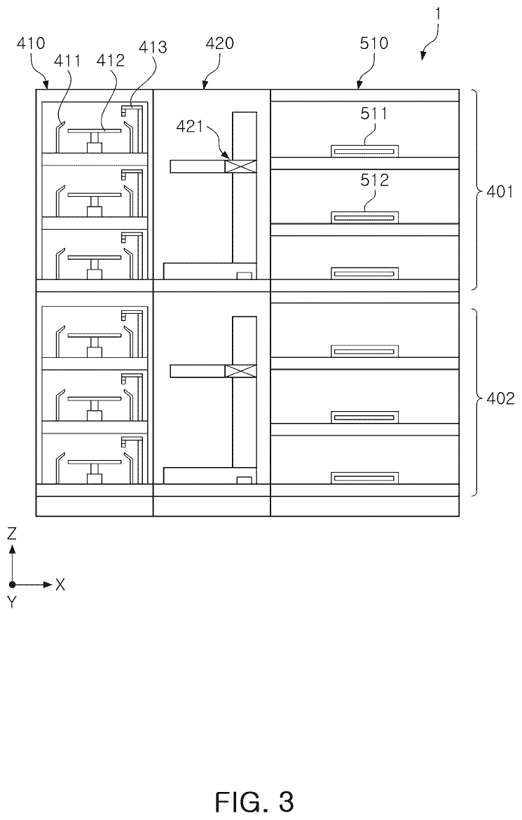

FIG. 1 is a top view of a substrate treatment apparatus according to an example embodiment of the present disclosure. FIG. 2 is a view of the substrate treatment apparatus of FIG. 1 taken along line A-A. FIG. 3 is a view of the substrate treatment apparatus of FIG. 1 taken along line B-B.

Referring to FIGS. 1 to 3, a substrate treatment apparatus 1 may include a load port 100, an index module 200, a buffer module 300, a coating and development module 400, and a purge module 700. The load port 100, the index module 200, the buffer module 300, the coating and development module 400, and an interface module 600 may be sequentially disposed in a line in one direction. The purge module 700 may be provided in the interface module 600. Alternatively, the purge module 700 may be provided in various positions such as a position to which an exposure device 800 at a rear end of the interface module 600 is connected, a side portion of the interface module 600, or the like.

Hereinafter, a direction in which the load port 100, the index module 200, the buffer module 300, the coating and development module 400, and the interface module 600 are disposed may be referred to as a first direction Y, a direction, perpendicular to the first direction Y when viewed from above, may be referred to as a second direction X, and a direction, perpendicular to each of the first direction Y and the second direction X, may be referred to as a third direction.

The substrate W may be moved in a state of being accommodated in a cassette 20. The cassette 20 may be sealed externally. As one example, a front open integrated pod (FOUP), having a door in front thereof, may be used as the cassette 20.

Hereinafter, the load port 100, the index module 200, the buffer module 300, the coating and development module 400, the interface module 600, and the purge module 700 will be described in detail.

The load port 100 may have a mounting table 120 on which the cassette 20 in which the substrate W is accommodated is disposed. The mounting table may be provided as a plurality of mounting tables 120, and the mounting tables 120 may be disposed in a line in the second direction X. FIG. 2 illustrates an example in which four mounting tables 120 are provided, but the number of mounting tables 120 may be changed.

The index module 200 may transfer the substrate W between the cassette 20 disposed on the mounting table 120 of the load port 100 and the buffer module 300. The index module 200 may include a frame 210, an index robot 220, and a guide rail 230. The frame 210 may have a substantially rectangular parallelepiped shape having an empty space therein, and may be disposed between the load port 100 and the buffer module 300. The frame 210 of the index module 200 may have a height, lower than that of a frame 310 of the buffer module 300. The index robot 220 and the guide rail 230 may be disposed in the frame 210. The index robot 220 may be provided such that a hand 221, directly handling the substrate W, is movable and rotatable in the first direction Y, the second direction X, and the third direction Z. The index robot 220 may include a hand 221, an arm 222, a support 223, and a pedestal 224. The hand 221 may be fixedly installed on the arm 222. The arm 222 may have a stretchable structure and a rotatable structure. The support 425 may be disposed such that a length direction thereof is the same as the third direction Z. The arm 222 may be coupled to the support 223 to be movable along the support 223. The support 223 may be fixedly coupled to the pedestal 224. The guide rail 230 may be disposed such that a length direction thereof is the same as the second direction X. The pedestal 224 may be coupled to the guide rail 230 to be linearly movable along the guide rail 230. In addition, although not illustrated, the frame 210 may further have a door opener for opening and closing a door of the cassette 20.

The buffer module 300 may include a frame 310, a first buffer 320, a second buffer 330, and a cooling chamber 340. The frame 310 may have a rectangular parallelepiped shape having an empty space therein, and may be disposed between the index module 200 and the coating and development module 400. The first buffer 320, the second buffer 330, and the cooling chamber 340 may be positioned in the frame 310. The cooling chamber 340, the second buffer 330, and the first buffer 320 may be sequentially disposed from the bottom in the third direction Z. The first buffer 320 may be positioned to have a height corresponding to that of a coating module 401 of the coating and development module 400, and the second buffer 330 and the cooling chamber 340 may be positioned to have a height corresponding to that of a development module 402 of the coating and development module 400.

The first buffer 320 and the second buffer 330 may temporarily store a plurality of substrates W, respectively. The first buffer 320 may have a housing 321 and a plurality of supports 322. In the first buffer 320, the supports 322 may be disposed in the housing 321, and may be spaced apart from each other in the third direction Z. The second buffer 330 may have a housing 331 and a plurality of supports 332. In the second buffer 330, the supports 332 may be disposed in the housing 331, and may be spaced apart from each other in the third direction Z. One substrate W may be disposed on each support 322 of the first buffer 320 and each support 332 of the second buffer 330. The housing 331 may have an opening in a direction in which the index robot 220 is provided, such that the index robot 220 may carry the substrate W into or out of the support 332 in the housing 331. The first buffer 320 may have a structure substantially similar to that of the second buffer 330. However, the housing 321 of the first buffer 320 may have openings in a direction in which a first buffer robot 360 is provided and in a direction in which a coating portion robot 421 positioned in the coating module 401 is provided. The number of supports 322 provided in the first buffer 320 may be equal to or different from the number of supports 332 provided in the second buffer 330. According to an example, the number of supports 332 provided in the second buffer 330 may be greater than the number of supports 322 provided in the first buffer 320.

The cooling chamber 340 may cool the substrate W. The cooling chamber 340 may include a housing 341 and a cooling plate 342. The cooling plate 342 may have an upper surface on which the substrate W is disposed, and a cooling means 343 for cooling the substrate W. Various methods, such as cooling using coolant or cooling using a thermoelectric element, may be used as the cooling means 343. In addition, the cooling chamber 340 may include a lift pin assembly for positioning the substrate W on the cooling plate 342. The housing 341 may have openings in a direction in which the index robot 220 is provided and in a direction in which a developing portion robot in the development module 402 is provided, such that the index robot 220 and the developing portion robot may carry the substrate W into or out of the cooling plate 342. In addition, doors for opening and closing the above-described openings may be provided in the cooling chamber 340.

In the above-described example embodiments, the buffer module 300 has been described to include the cooling chamber 340, but the present disclosure is not limited thereto. The cooling chamber 340 may be omitted, as necessary.

The coating module 401 may include a process of coating a photosensitive liquid, such as a photoresist, on the substrate W, and a heat treatment process, such as heating and cooling of the substrate W, before and after a resist coating process. The coating module 401 may have a coating chamber 410, a heat treatment chamber portion 500, and a conveyance chamber 420. The coating chamber 410, the conveyance chamber 420, and the heat treatment chamber portion 500 may be sequentially disposed in the second direction X. That is, with respect to the conveyance chamber 420, the coating chamber 410 may be disposed on one side of the conveyance chamber 420, and the heat treatment chamber portion 500 may be disposed on the other side of the conveyance chamber 420.

The coating chamber 410 may be provided as a plurality of coating chambers 410 in the third direction Z. In addition, as illustrated in FIG. 1, the coating chamber 410 may be provided as a plurality of coating chambers 410 in the first direction Y and as one coating chamber 410 in the first direction Y. The heat treatment chamber portion 500 may include a baking chamber 510 and a cooling chamber 520, and the baking chamber 510 and the cooling chamber 520 may be provided as a plurality of baking chambers 510 and a plurality of cooling chambers 520 in the third direction Z, respectively. The conveyance chamber 420 may be positioned to be parallel to the first buffer 320 of the first buffer module 300 in a first direction 12. The coating portion robot 421 and the guide rail 422 may be positioned in the conveyance chamber 420. The conveyance chamber 420 may have a substantially rectangular shape. The coating portion robot 421 may transfer the substrate W, between the baking chamber 510, the cooling chamber 520, the coating chamber 410, and the first buffer 320 of the first buffer module 300.

The guide rail 422 may be disposed such that a length direction thereof is parallel to the first direction Y. The guide rail 422 may guide the coating portion robot 421 to linearly move in the first direction Y. The coating portion robot 421 may have a hand 423, an arm 424, a support 425, and a pedestal 426. The hand 423 may be fixedly installed on the arm 424. The arm 424 may have a stretchable structure, such that the hand 423 may move in a horizontal direction. The support 425 may be disposed such that a length direction thereof is the same as the third direction Z. The arm 424 may be coupled to the support 425 so as to be linearly movable in the third direction Z along the support 425. The support 425 may be fixedly coupled to the pedestal 426, and the pedestal 426 may be coupled to the guide rail 422 so as to be movable along the guide rail 422.

All of the coating chambers 410 may have the same structure. However, types of treatment liquids, respectively used in the coating chambers 410, may be different from each other. A treatment liquid for forming a photoresist film or an antireflection film may be used as the treatment liquid.

The coating chamber 410 may coat a treatment liquid on the substrate W. A treatment unit, including a cup portion 411, a support portion 412, and a nozzle portion 413, may be provided in the coating chamber 410.

As one example, one treatment unit may be disposed in each coating chamber 410 in the first direction Y, but the present disclosure is not limited thereto, and two or more treatment units may be disposed in a single coating chamber 410. The treatment units may all have the same structure. However, types of treatment liquids, respectively used in the treatment units, may be different from each other.

The treatment container 411 of the coating chamber 410 may have a shape having an open upper portion. The support portion 412 may be disposed in the treatment container 411, and may support the substrate W. The support portion 412 may be rotatably provided. The nozzle portion 413 may supply a treatment liquid onto the substrate W disposed on the support portion 412. The treatment liquid may be coated on the substrate W in a spin-coating manner. In addition, the coating chamber 410 may further selectively include a nozzle (not illustrated) for supplying a cleaning liquid such as deionized water (DIW) to clean a surface of the substrate W on which the treatment liquid is coated, and a back rinse nozzle (not illustrated) for cleaning a lower surface of the substrate W.

In the baking chamber 510, when the substrate W is mounted by the coating portion robot 421, the substrate W may be heat-treated.

In the baking chamber 510, a pre-baking process of removing organic matter or moisture from a surface of the substrate W by heating the substrate W to a predetermined temperature may be performed before the treatment liquid is coated, or a soft baking process may be performed after the treatment liquid is coated on a wafer W, and a cooling process of cooling the substrate W may be performed after each heating process.

A heating plate 511 and a cooling plate 512 may be provided in the baking chamber 510. A cooling means such as coolant or a thermoelectric element may be provided in the cooling plate 512.

The cooling chamber 520 may perform a cooling process of cooling the substrate W before the treatment liquid is coated. The cooling chamber 520 may include a cooling plate. The cooling plate may include a cooling means in which various methods, such as cooling using a coolant or cooling using a thermoelectric element, are used to cool the substrate W.

The interface module 600 may connect the coating and development module 400 to an external exposure device 800. The interface module 600 may include an interface frame 610, a first interface buffer 620, a second interface buffer 630, and a conveyance robot 640, and the conveyance robot 640 may convey, to the exposure device 800, the substrate conveyed to the first and second interface buffers 620 and 630 after the coating and development module 400 is terminated. The first and second interface buffers 620 may include a housing 621 and a support 622, and the conveyance robot 640 and the coating portion robot 421 may carry the substrate W into/out of the support 622.

Hereinafter, an example embodiment of the present disclosure may be applicable to a coating chamber 410, and may also be applicable not only to the coating chamber 410 but also to various types of chambers.

In addition, a liquid described hereinafter may include a cleaning liquid used in a cleaning process of a substrate, and more specifically, may include a two-phase fluid in which gas and liquid are mixed and sprayed in fine particles, or deionized water (DI).

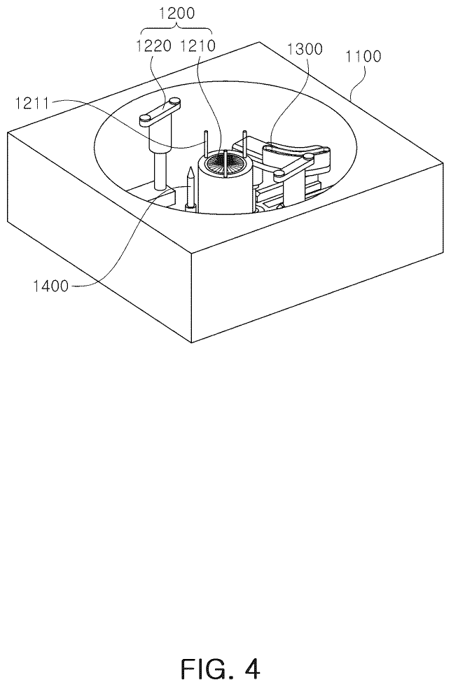

FIG. 4 is a perspective view of a substrate treatment apparatus according to an example embodiment of the present disclosure.

Referring to FIG. 4, the substrate treatment apparatus according to an example embodiment of the present disclosure may include a treatment container 1100, a support portion 1200, a rotary nozzle unit 1300, a fixed nozzle unit 1400, and a controller (not illustrated).

The treatment container 1100 may have an internal processing space in which a substrate is treated. The treatment container may serve to prevent a treatment liquid supplied to the substrate during a process from scattering. In the internal processing space of the treatment container 1100, the support portion 1200, the rotary nozzle unit 1300, and the fixed nozzle unit 1400 may be disposed.

In an example embodiment, the treatment container 1100 may have a hexahedral shape having an upper surface having a circular opening. In the processing space, a cleaning liquid may be sprayed onto a lower surface of a substrate. In an example embodiment, the rotary nozzle unit may perform rotational motion and vertical motion to spray a treatment liquid onto a central region and an edge region of the lower surface of the substrate, and the fixed nozzle unit may perform vertical motion to spray the treatment liquid onto the lower surface of the substrate. The rotary nozzle unit and the fixed nozzle unit will be described below in detail.

The support portion 1200 may include a spin chuck 1210 and a side chuck 1220.

The spin chuck 1210 may be provided in the processing space to support the substrate. The spin chuck 1210 may rotate the substrate while a treatment operation is performed on the substrate. By rotating the substrate, the treatment liquid may be evenly sprayed onto the lower surface of the substrate. In an example embodiment, the spin chuck 1210 may include a spin head, a support plate, a rotary driving member, and the like.

The spin chuck 1210 may further include a plurality of support pins 1211. The plurality of support pins may be in contact with the lower surface of the substrate. While the treatment operation for the substrate is performed in the processing space, the plurality of support pins may support the substrate. In an example embodiment, when the substrate is carried into or out of the processing space, the plurality of support pins may be lowered or raised.

The side chuck 1220 may vacuum-adsorb and support the edge region of the lower surface of the substrate. In other words, The side chuck 1220 may vacuum chuck the edge region of the lower surface of the substrate. In an example embodiment, the side chuck 1220 may be configured as two side chucks 1220, and the two side chucks 1220 may support and fix both sides of an edge of the lower surface of the substrate in an absorbing manner while the central region of the lower surface of the substrate is cleaned.

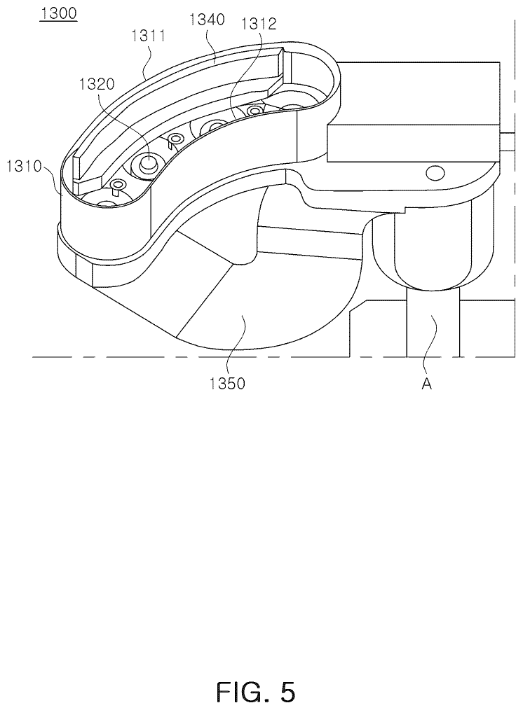

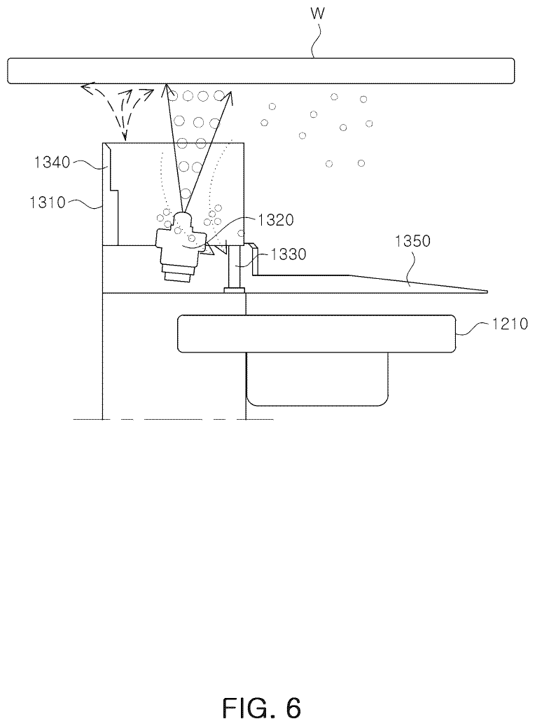

FIG. 5 is a perspective view of a rotary nozzle unit according to an example embodiment of the present disclosure. FIG. 6 is a cross-sectional view of a rotary nozzle unit according to an example embodiment of the present disclosure.

Referring to FIGS. 5 and 6, the rotary nozzle unit 1300 may include a housing 1310, a nozzle portion 1320, an intake portion 1330, a gas injection portion 1340, a cover member 1350, and a drive unit (not illustrated).

The rotary nozzle unit 1300 may be configured to rotate about a rotational shaft A and to spray a treatment liquid onto the central region of the lower surface of the substrate or the edge region of the lower surface of the substrate.

According to an example embodiment, the housing 1310 may have an arcuate curved shape. The arcuate housing 1310 may include a first curved surface 1311 forming an outer circumference, and a second curved surface 1312 forming an inner circumference. In this case, the first curved surface 1311 may have an area larger than that of the second curved surface 1312.

The housing 1310 may perform rotational motion about the rotational shaft. In this case, the rotational shaft may be formed on the outside of the housing 1310 without passing through an internal space of the housing 1310.

The rotary nozzle unit 1300 may rotate in a reciprocating manner within a predetermined angular range about the rotational shaft to clean the central region of the lower surface of the substrate or the edge region of the lower surface of the substrate.

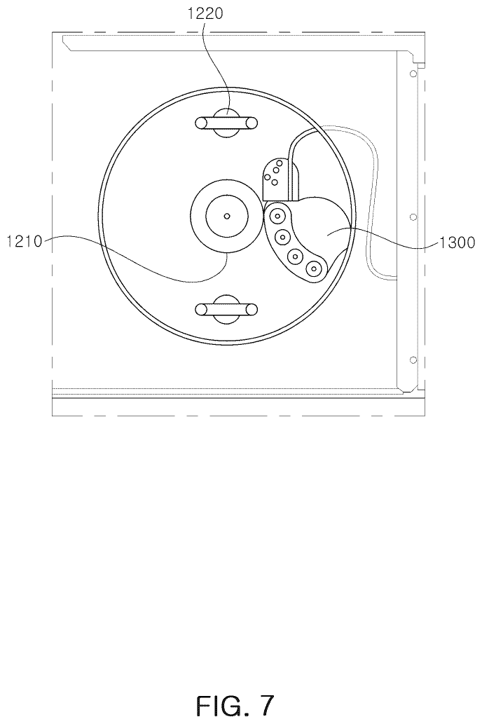

FIGS. 7 to 10 illustrate an example embodiment in which a rotary nozzle unit rotates about a rotational shaft at a predetermined angle.

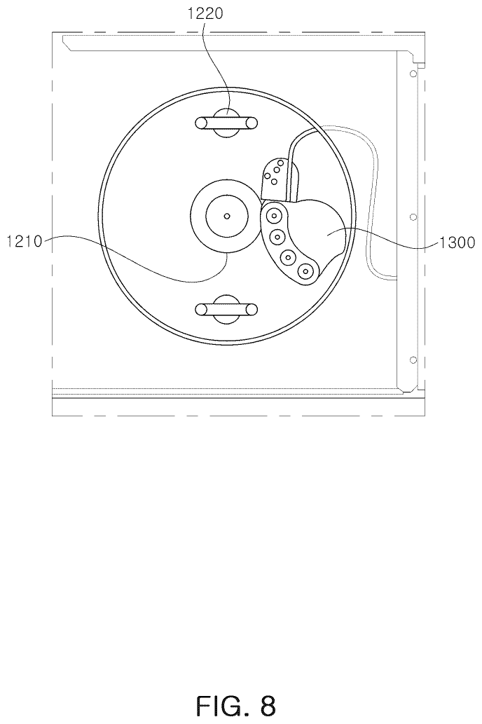

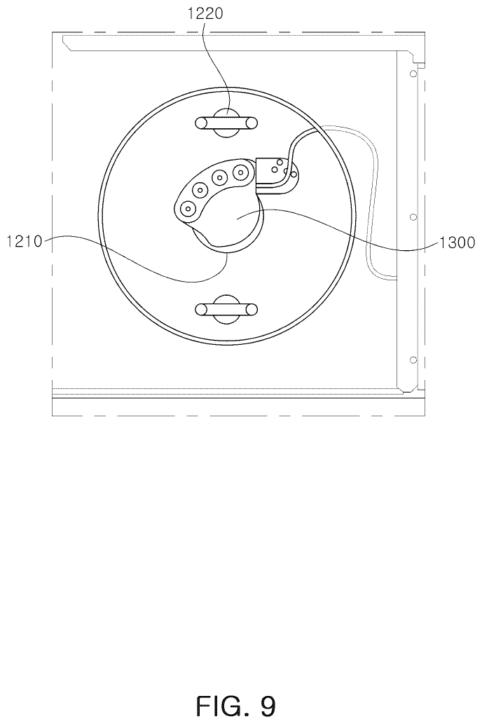

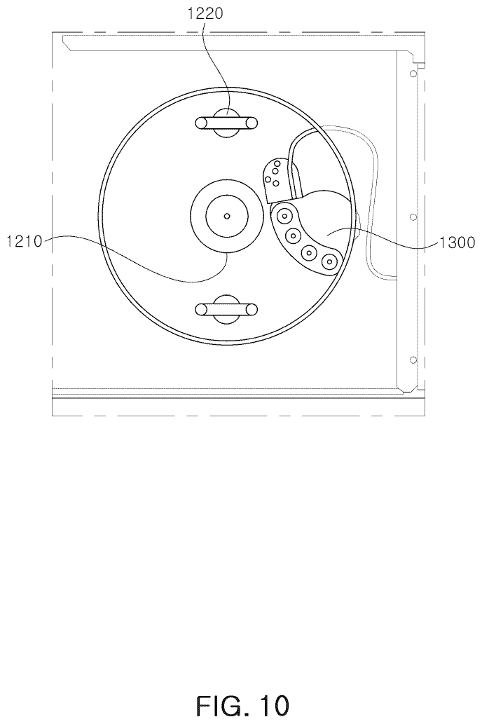

Referring to FIGS. 7 to 10, an angle of the rotary nozzle unit illustrated in FIG. 7 may be defined as 0°. An angle of the rotary nozzle unit illustrated in FIG. 8 may be defined as 5°. An angle of the rotary nozzle unit illustrated in FIG. 9 may be defined as 95°, and an angle of the rotary nozzle unit illustrated in FIG. 10 may be defined as −10°.

In an example embodiment, when the rotary nozzle unit 1300 cleans the central region of the lower surface of the substrate, the rotary nozzle unit 1300 may rotate in a reciprocating manner within an angular range of 5° to 95° to spray a cleaning liquid onto the lower surface of the substrate.

In an example embodiment, when the edge region of the lower surface of the substrate is cleaned, the rotary nozzle unit 1300 may rotate in a reciprocating manner within an angular range of 5° to −10 ° to spray a cleaning liquid onto the lower surface of the substrate.

Referring back to FIGS. 2 and 3, the nozzle portion 1320 may be provided in the internal space of the housing 1310 to spray a treatment liquid toward the lower surface of the substrate. The nozzle portion 1320 may include a plurality of nozzles, and the plurality of nozzles may be disposed in a straight line or may be disposed in an arc shape along the arcuate housing 1310. In an example embodiment, the nozzle portion 1320 may spray a two-phase fluid in which liquid and gas are mixed in the form of mist.

The gas injection portion 1340 may be provided along one surface of an inner wall of the housing 1310 to inject gas. In an example embodiment, the gas injection portion 1340 may be provided along an inner wall of the first curved surface 1311 of the housing 1310 having an arcuate curved shape.

The gas injection portion 1340 may be disposed in the internal space of the housing 1310, and may inject compressed air or gas toward the lower surface of the substrate in an upward direction at high pressure to form an air curtain.

In an example embodiment, the arcuate housing 1310 may have a first curved surface 1311 forming an outer circumference, and a second curved surface forming an inner circumference. The gas injection portion 1340 may be disposed along the first curved surface 1311 forming the outer circumference. The injected cleaning liquid may not scatter toward the outside of the first curved surface 1311 due to the air curtain formed along the first curved surface 1311, and may scatter toward the inside of the housing 1310 or the second curved surface forming the inner circumference.

The gas injection portion 1340 may supply a predetermined gas to the lower surface of the substrate. In an example embodiment, the gas supply portion 344 may supply an inert gas such as nitrogen toward the lower surface of the substrate W. Alternatively, the gas supply portion 344 may supply air, such as clean dry air (CDA). The gas supply portion 344 may be configured to receive gas from a gas supply source.

In an example embodiment, the gas injection portion 1340 may inject gas in a direction, substantially perpendicular to the lower surface of the substrate, to form an air curtain. By forming the air curtain, the gas injection portion 1340 may prevent particles floating in the processing space from being reattached to the central region of the lower surface of the substrate. In addition, the gas injection portion 1340 may remove a treatment liquid that may remain on the lower surface of the substrate. Alternatively, the gas injection portion 1340 may be used in a process for drying the substrate after a cleaning process on the substrate is performed. In an example embodiment, the gas injection portion 1340 may be provided in the form of an air knife.

The intake portion 1330 may suction a treatment liquid accumulated in the housing 1310 and a treatment liquid scattering in the form of mist. In an example embodiment, the intake portion 1330 may provide a plurality of intake holes provided on a lower surface of the housing 1310. The intake portion 1330 may be connected to an exhaust line and a suction source to discharge a suctioned fluid to the outside of the substrate treatment apparatus. The intake portion 1330 may form a negative pressure in the internal space of the housing 1310 to effectively suction particles floating in the air.

The cover member 1350 may be configured to protrude outwardly from a lower portion of the rotary nozzle unit 1300. More specifically, the cover member 1350 may be configured to protrude outwardly from the second curved surface 1312 forming an inner circumference of the housing 1310. A direction in which the cover member 1350 is disposed may be a direction opposing the first curved surface 1311 on which the gas injection portion 1340 is disposed. Due to the air curtain formed by the gas injection portion 1340, a treatment liquid sprayed from the nozzle portion 1320 may not scatter toward the first curved surface 1311 on which the gas injection portion 1340 is disposed, and may scatter toward the second curved surface 1312 on which the gas injection portion 1340 is not disposed.

The rotary nozzle unit 1300 may rotationally move to an upper portion of the spin chuck 1210. In this case, an treatment liquid may fall onto the spin chuck 1210, causing contamination of the spin chuck 1210. The cover member 1350 may serve to prevent the falling treatment liquid from reaching the spin chuck 1210.

The drive unit (not illustrated) may drive the rotary nozzle unit 1300 to rotate about the rotational shaft and to move in a vertical direction.

The drive unit may transmit power to the rotational shaft having a cylindrical rod shape, such that the rotational shaft may perform rotational motion. The drive unit may provide power, such that the rotary nozzle unit 1300 may be raised or lowered.

The fixed nozzle unit 1400 may be provided in a fixed position in the processing space of the treatment container 1100, and may move in a vertical direction to spray a treatment liquid onto the lower surface of the substrate. In an example embodiment, the fixed nozzle unit 1400 may spray deionized water. In an example embodiment, the fixed nozzle unit 1400 may clean the edge region of the lower surface of the substrate, together with the rotary nozzle unit 1300.

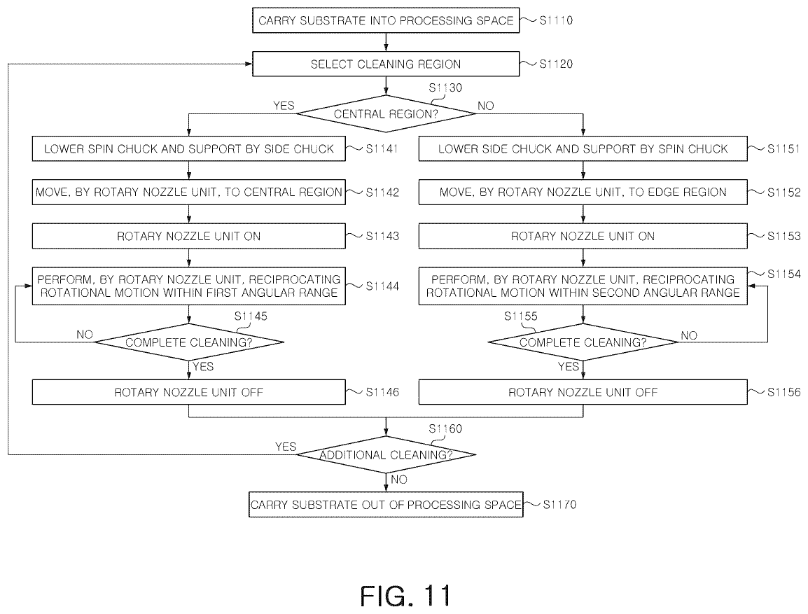

The controller (not illustrated) may control the treatment container 1100, the support portion 1200, the rotary nozzle unit 1300, and the fixed nozzle unit 1400. An operation of the controller will be described below with reference to FIG. 11.

FIG. 11 is a flowchart of a substrate treatment method according to an example embodiment of the present disclosure.

Referring to FIG. 11, first, a substrate may be carried into a processing space of a treatment container 1100 (S1110). A controller may select whether to clean a central region of a lower surface of the substrate or an edge region of the lower surface of the substrate (S1120). In an example embodiment, the controller may clean the central region of the lower surface of the substrate, and then may clean the edge region of the lower surface of the substrate. A cleaning region of the substrate may be selected according to a user input or a preset sequence.

When the central region of the lower surface of the substrate is selected as the cleaning region (S1130), three pins provided to a spin chuck 1210 may be lowered, and a side chuck 1220 may vacuum chuck the edge region of the lower surface of the substrate (S1141). A rotary nozzle unit 1300 may move to a position corresponding to the central region of the lower surface of the substrate (S1142).

A nozzle portion 1320, a gas injection portion 1340, and an intake portion 1330 of the rotary nozzle unit 1300 may be switched to an ON state (S1143). That is, the nozzle portion 1320, the gas injection portion 1340, and the intake portion 1330 of the rotary nozzle unit 1300 may be activated.

Thereafter, the rotary nozzle unit 1300 may rotate in a reciprocating manner within a first angular range for cleaning the central region of the lower surface of the substrate (S1144). In an example embodiment, the rotary nozzle unit 1300 may perform reciprocating motion within an angle range of 5° to 95° to clean the central region of the lower surface of the substrate.

The controller may determine whether cleaning is completed (S1145). When cleaning is completed, the controller may switch the nozzle portion 1320, the gas injection portion 1340, and the intake portion 1330 of the rotary nozzle unit 1300 to an OFF state (S1146). That is, The controller may deactivate the nozzle portion 1320, the gas injection portion 1340, and the intake portion 1330 of the rotary nozzle unit 1300 upon completion of the cleaning.

When the edge region of the lower surface of the substrate is selected as the cleaning region (S1130), the side chuck 1220 may be lowered, and the spin chuck 1210 may support the central region of the lower surface of the substrate and rotate the substrate(S1151). The rotary nozzle unit 1300 may move to a position corresponding to the edge region of the lower surface of the substrate (S1152).

The nozzle portion 1320, the gas injection portion 1340, and the intake portion 1330 of the rotary nozzle unit 1300 may be switched to an ON state (S1153). In this case, the fixed nozzle unit 1400 may be switched to an ON state, and may spray a treatment liquid onto the edge region of the substrate.

The rotary nozzle unit 1300 may rotate in a reciprocating manner within a second angular range for cleaning the edge region of the lower surface of the substrate (S1154). In an example embodiment, the rotary nozzle unit 1300 may perform reciprocating motion within an angle range of 5° to −10 ° to clean the edge region of the lower surface of the substrate.

The controller may determine whether cleaning is completed (S1155). When cleaning is completed, the controller may switch the nozzle portion 1320, the gas injection portion 1340, and the intake portion 1330 of the rotary nozzle unit 1300 to an OFF state (S1156). That is, The controller may deactivate the nozzle portion 1320, the gas injection portion 1340, and the intake portion 1330 of the rotary nozzle unit 1300 upon completion of the cleaning.

Thereafter, the controller may determine whether additional cleaning is necessary (S1160). When additional cleaning is necessary, the process may return to operation S1120. When additional cleaning is not necessary, the cleaning process may be terminated, and the substrate may be carried out of the internal processing space (S1170).

While example embodiments have been shown and described above, it will be apparent to those skilled in the art that modifications and variations could be made without departing from the scope of the present disclosure as defined by the appended claims.

1. A substrate treatment apparatus comprising:
a treatment container having a processing space for a substrate;
a support portion provided in the processing space, and configured to support the substrate; and
a rotary nozzle unit provided in the processing space, the rotary nozzle unit configured to spray a treatment liquid onto a central region of a lower surface of the substrate by rotating about a rotational shaft within a first angular range, and to spray the treatment liquid onto an edge region of the lower surface of the substrate by rotating about the rotational shaft within a second angular range.

2. The substrate treatment apparatus of claim 1, wherein the rotary nozzle unit includes:
a housing formed in a cup shape, and having an arcuate curved surface, an internal space and an upper opening; and
a nozzle portion provided in the internal space of the housing, and configured to spray the treatment liquid toward the lower surface of the substrate.

3. The substrate treatment apparatus of claim 2, wherein the rotary nozzle unit further includes an intake portion provided in the internal space of the housing, and configured to intake the sprayed treatment liquid.

4. The substrate treatment apparatus of claim 2, wherein the rotary nozzle unit further includes a gas injection portion provided along an inner wall of a first curved surface of the housing having the arcuate curved shape, and configured to inject gas to form an air curtain.

5. The substrate treatment apparatus of claim 4, wherein the rotary nozzle unit further includes a cover member protruding outwardly from a second curved surface opposing the first curved surface.

6. The substrate treatment apparatus of claim 2, wherein the rotary nozzle unit further includes a drive unit configured to rotate the rotary nozzle unit about the rotational shaft and to move the rotary nozzle unit in a vertical direction.

7. The substrate treatment apparatus of claim 2, wherein the nozzle portion includes a plurality of nozzles disposed along an arcuate shape.

8. The substrate treatment apparatus of claim 1, wherein the support portion includes:
a spin chuck configured to support the central region of the lower surface of the substrate; and
a side chuck configured to support the edge region of the lower surface of the substrate.

9. The substrate treatment apparatus of claim 8, wherein when the rotary nozzle unit cleans the central region of the lower surface of the substrate, the spin chuck is lowered, and the side chuck vacuum chucks the edge region of the lower surface of the substrate.

10. The substrate treatment apparatus of claim 8, wherein when the rotary nozzle unit cleans the edge region of the lower surface of the substrate, the side chuck is lowered, and the spin chuck supports the central region of the lower surface of the substrate and to rotate the substrate.

11. The substrate treatment apparatus of claim 1, further comprising:
a fixed nozzle unit configured to be fixed in the processing space, and to spray a cleaning liquid onto the lower surface of the substrate.

12. The substrate treatment apparatus of claim 1, further comprising:
a controller configured to control operation of the support portion and the rotary nozzle unit.

13. The substrate treatment apparatus of claim 12, wherein when the rotary nozzle unit cleans the central region of the lower surface of the substrate, the controller is configured to:
control the rotary nozzle unit to move to a position corresponding to the central region of the lower surface of the substrate;
control the nozzle portion, the gas injection portion, and the intake portion included in the rotary nozzle unit to be activated; and
control the rotary nozzle unit to rotate in a reciprocating manner within the first angular range corresponding to the central region of the lower surface of the substrate.

14. The substrate treatment apparatus of claim 13, wherein the controller is configured to control the nozzle portion, the gas injection portion, and the intake portion included in the rotary nozzle unit to be deactivated upon completion of the cleaning of the central region of the lower surface of the substrate.

15. The substrate treatment apparatus of claim 12, wherein when the rotary nozzle unit cleans the edge region of the lower surface of the substrate, the controller is configured to:
control the rotary nozzle unit to move to a position corresponding to the edge region of the lower surface of the substrate;
control the nozzle portion, the gas injection portion, and the intake portion included in the rotary nozzle unit to be activated; and
control the rotary nozzle unit to rotate in a reciprocating manner within the second angular range corresponding to the edge region of the lower surface of the substrate.

16. The substrate treatment apparatus of claim 15, wherein, the controller is configured to control the nozzle portion, the gas injection portion, and the intake portion included in the rotating nozzle unit to be deactivated upon completion of the cleaning of the edge region of the lower surface of the substrate.

17.-19. (canceled)

20. A substrate treatment apparatus comprising:
a treatment container having a processing space for a substrate;
a support portion provided in the processing space, and configured to support the substrate; and
a rotary nozzle unit provided in the processing space, and configured to spray a treatment liquid onto a central region of a lower surface of the substrate by rotating about a rotational shaft within a first angular range, and to spray the treatment liquid onto an edge region of the lower surface of the substrate by rotating about the rotational shaft within a second angular range,
wherein the rotary nozzle unit comprises:
a housing formed in a cup shape, and having an arcuate curved surface, an internal space and an upper opening;
a nozzle portion provided in the internal space of the housing, and configured to spray a treatment liquid toward the lower surface of the substrate;
an intake portion provided in the internal space of the housing, and configured to intake the sprayed treatment liquid;
a gas injection portion provided along an inner wall of a first curved surface of the housing having the arcuate curved shape, and configured to inject gas to form an air curtain;
a cover member protruding outwardly from a second curved surface opposing the first curved surface; and
a drive unit configured to rotate the rotary nozzle unit about the rotational shaft and to move the rotary nozzle unit in a vertical direction.
